(19) United States
(12) Patent Application Publication
(10) Pub. No.: US 2016/0033597 A1
(43) Pub. Date: Feb. 4, 2016

(54) GALLIUM ARSENIDE (GAAS) BASED AMPLIFIER AND TRANSMIT/ RECEIVE SWITCH FOR CRYOGENIC DEVICES AND RELATED SYSTEMS AND METHODS

(71) Applicant: Agilent Technologies, Inc., Santa Clara, CA (US)

(72) Inventor: Zhenghong Gong, San Jose, CA (US)

(21) Appl. No.: 14/446,546

(22) Filed: Jul. 30, 2014

(51) Int. Cl. G01R 33/36; G01R 33/34

(52) U.S. Cl. CPC G01R 33/3664; G01R 33/3614; G01R 33/34023; G01R 33/3403

(57) ABSTRACT

A cryogenic switching device includes a radio frequency (RF) signal input node, a coil interface, an RF signal output node, and a plurality of gallium arsenide (GaAs) diode units configured for transmitting an RF input signal from the RF signal input node to the coil interface, and an RF output from the coil interface to the signal output node. The device may be operative at temperatures below 77 K, and may be utilized as a transmit/receive switch in a nuclear magnetic resonance (NMR) cold probe for increasing NMR sensitivity, obtaining a strong NMR spectrum with reduced or non-noticeable amplitude and phase distortion.

### TECHNICAL FIELD

The present invention relates generally to systems and methods for a gallium arsenide

(GaAs) based amplifier and transmit and receive switch that may be implemented in cryogenic devices. As one example, the cryogenic device may be part of a nuclear magnetic resonance (NMR) cold probe to provide signal to noise enhancement.

### BACKGROUND

A cryogenic device is generally a device that is cooled by a cryogenic system, i.e., a system utilizing a cryogen (e.g., liquid nitrogen, liquid helium, cold helium gas) as the heat transfer medium. Cryogenic cooling may be implemented for various purposes, for example to maintain the operating temperature of a superconducting device at or below the critical temperature required for superconductivity, or to provide highly effective cooling of a device that dissipates a relatively large amount of electrical power and thus heat (thermal energy). One example of a high power dissipating device is a nuclear magnetic resonance (NMR) apparatus, which transmits pulsed, high-intensity radio frequency (RF) power and thus generates a large amount of heat on a fast time scale. An NMR apparatus may be configured for cryogenic cooling, as described below.

An NMR apparatus is utilized to obtain useful information from a sample of interest. The sample may be a chemical specimen (e.g., a contained liquid or solid object) or a biological organism (e.g., a human or animal). An NMR apparatus may be configured as an NMR spectrometer that obtains spectral data indicative of molecular structure, position and abundance. An NMR apparatus may also be configured as a (nuclear) magnetic resonance imaging (MRI) apparatus that obtains imaging data indicative of the position and pathology of tissues and organs.

In a typical NMR apparatus, an NMR tube (typically a thin-walled glass tube) containing the sample is loaded into an NMR probe such that the sample is surrounded by one or more radio frequency (RF) coils of the NMR probe. The NMR probe is inserted into a bore that is surrounded by a magnet, which is often a superconducting magnet and typically of the type requiring cryogenic cooling. The magnet generates a high-strength (typically a few to several Tesla) static magnetic field, or B₀ field, along the central axis of the magnet bore, or z-axis. NMR-active nuclei of the sample, such as protons (hydrogen nuclei) and carbon-13 nuclei, behave as magnetic dipoles and become aligned with the B₀ field along the z-axis. Adjustable-position gradient “shim” coils (shims) positioned in the bore are utilized to correct inhomogeneities in the applied B₀ field.

One of the RF coils is utilized as a transmit coil to apply a pulsed magnetic field, or B₁ field, to the sample. The B₁ field is typically orthogonal to the B₀ field and oscillates in the RF range (i.e., on the order of 10 MHz to 1 GHz). The transmit coil is tuned to resonantly excite the NMR-active nuclei of interest in the sample. During the delay interval between pulses the excited nucleus emits an RF time-domain signal, or NMR measurement signal, which is received by the RF coil (the receive coil or pick-up coil, which may be the same coil utilized for excitation or a different coil). Electronics of the NMR system amplify and process the NMR measurement signal as needed to construct an NMR spectrum containing information regarding the irradiated sample.

The signal-to-noise ratio (S/N) of the RF receiver electronics provides a quantification of the sensitivity of the NMR apparatus. Thermal noise in the signal detection pathway of the portion of the RF receiver electronics located in the NMR probe (receive coil, preamplifier, and associated circuitry) significantly limits the sensitivity. Thermal noise from a resistance R may be expressed in terms of noise voltage as (4kTRB)^{1/2}, or in terms of noise current as ((4kTB)/R)^{1/2}, where Boltzmann's constant k =1.38×10⁻³⁸ Joules/Kelvin (J/K), T is absolute temperature in Kelvin, R is resistance in ohms (Q), and B is bandwidth in Hertz (Hz). It follows that lowering the temperature of the RF coil, preamplifier and other electronics in the NMR probe will reduce noise and consequently increase S/N and therefore sensitivity. Cryogenically cooled probes (or “cold” probes) have been developed for this purpose. In a typical NMR cold probe, cold helium from an external cooling system (separate from the magnet cooling system) circulates through a heat exchanger inside the probe, such that heat is removed from the RF coil and preamplifier and carried away from the probe. The typical operating temperature of a cryogenically cooled RF coil, preamplifier and associated circuitry may range from about 15 to 30 K. NMR cold probes have achieved three- to four-fold increases in sensitivity over conventional RT probes. Thus, for a given sample concentration NMR cold probes require significantly less time for making measurements. Moreover, NMR cold probes enable measurements of significantly smaller sample concentrations (e.g., micrograms versus milligrams).

As described further below, electronics provided in the NMR probe (referred to as NMR probe circuitry) may include a transmit/receive (T/R) switch and one or more amplifier stages such as low noise amplifiers (LNAs) or ultra low noise amplifiers (ultra LNAs). Conventionally, the T/R switch is silicon (Si) based because of the relatively long carrier lifetime, and higher power handling characteristics of Si. While the Si based T/R switches have good power handling abilities, Si based T/R switches have a low temperature operating range limitation of approximately 77 K, due to charge carriers freezing at temperatures below 77 K. Consequently, suppression of thermal noise in conventional T/R switches is not optimal.

Therefore, there is a need to provide T/R switches capable of operating effectively at lower cryogenic temperatures than have been achieved thus far in conventional designs, i.e., lower than 77 K or significantly lower than 77 K. There is also a need to provide T/R switches that exhibit improved power handling capabilities while operating at such lower cryogenic temperatures. There is also a need to provide T/R switches that offer adequate over-power protection to power-sensitive components such as LNAs.

### SUMMARY

To address the foregoing problems, in whole or in part, and/or other problems that may have been observed by persons skilled in the art, the present disclosure provides methods, processes, systems, apparatus, instruments, and/or devices, as described by way of example in implementations set forth below.

According to one embodiment, a cryogenic switching device includes: a radio frequency (RF) signal input node; a coil interface; a signal output node; and a plurality of gallium arsenide (GaAs) diode units in communication with the RF signal input node, the coil interface and the signal output node, and arranged to transmit a RF signal from the RF signal input node to the coil interface, and to transmit a measurement signal from the coil interface to the signal output node.

According to another embodiment, each of the GaAs diode units includes at least one GaAs p-type-intrinsic-n-type (PIN) diode.

According to another embodiment, each of the GaAs diode units is in communication with a transmission line.

According to another embodiment, the plurality of GaAs diode units includes a first GaAs diode unit positioned in communication between the RF signal input node and the transmission line.

According to another embodiment, the first GaAs diode unit includes a plurality of GaAs PIN diodes, arranged electrically parallel to each other.

According to another embodiment, the plurality of GaAs diode units includes a second GaAs diode unit positioned in communication between the transmission line and a ground rail node.

According to another embodiment, the second GaAs diode unit includes a plurality of GaAs PIN diodes, arranged electrically parallel to each other.

According to another embodiment, the second GaAs diode unit includes a resistor-capacitor circuit.

According to another embodiment, the plurality of GaAs diode units includes one or more shunt diode units placed in a shunt position relative to the transmission line.

According to another embodiment, the first GaAs diode unit and the one or more shunt diode units are configured to be biased in a conductive state in response to a bias current applied to the RF signal input node.

According to another embodiment, one or more of the shunt diode units include a plurality of GaAs PIN diodes arranged electrically parallel or anti-parallel to each other.

According to another embodiment, one or more of the shunt diode units include a plurality of GaAs PIN diodes arranged electrically parallel to each other, and include a resistor-capacitor circuit

According to another embodiment, the plurality of GaAs diode units is configured for transmitting the RF input signal as an NMR excitation signal and for transmitting an RF output signal as an NMR measurement signal.

According to another embodiment, a cryogenic signal processing device includes: a cryogenic switching device according to any of the embodiments disclosed herein; and an amplifier in communication with the cryogenic switching device.

In some embodiments, the amplifier is a GaAs amplifier positioned in communication between the plurality of GaAs diode units and the signal output node.

In some embodiments, the amplifier is a pseudomorphic high-electron-mobility transistor (pHEMT) amplifier.

According to another embodiment, the cryogenic signal processing device includes a high pass filter coupled to the coil interface.

In some embodiments, the cryogenic signal switching device or cryogenic signal processing device has a noise temperature of less than 10 K when operated at 35 K or lower.

In some embodiments, the cryogenic signal switching device or cryogenic signal processing device is configured to operate with a RF signal power input range of 0.02 W to 50 W.

According to another embodiment, a nuclear magnetic resonance (NMR) probe includes: a cryogenic switching device or a cryogenic signal processing device according to any of the embodiments disclosed herein; and a radio frequency (RF) coil in communication with the coil interface.

According to another embodiment, the NMR probe includes a heat exchanger configured for cooling the cryogenic switching device and the RF coil.

According to another embodiment, the NMR probe includes an amplifier in communication with the cryogenic switching device, wherein the heat exchanger is configured for cooling the signal amplifier.

According to another embodiment, the heat exchanger includes a coolant supply conduit configured for conducting coolant toward the cryogenic switching device and the RF coil, and a coolant return conduit configured for conducting coolant away from the cryogenic switching device and the RF coil.

According to another embodiment, a nuclear magnetic resonance (NMR) apparatus includes: an NMR probe according to any of the embodiments disclosed herein; and one or more other devices such as, for example, a cryogenic cooler configured for communicating with the heat exchanger, a magnet surrounding the NMR probe, and/or a control/acquisition system configured for communicating with the NMR probe.

In some embodiments, the NMR apparatus includes a superconducting magnet. In some embodiments, the magnet is a high-temperature superconducting magnet.

In some embodiments, the NMR apparatus includes a bore in which the NMR probe is removably positioned, and an outer vacuum case coupled to the bore and enclosing the magnet, wherein the magnet surrounds the bore.

Other devices, apparatus, systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The invention can be better understood by referring to the following figures. The components in the figures are not necessarily to scale, emphasis instead being placed upon illustrating the principles of the invention. In the figures, like reference numerals designate corresponding parts throughout the different views.

FIG. 1 is a schematic view of an example of a nuclear magnetic resonance (NMR) apparatus and associated system according to some embodiments.

FIG. 2 is block diagram of an example of a transmit/receive (T/R) switch unit interfaced with a radio frequency (RF) coil, RF transmission circuitry, and RF receiving circuitry according to some embodiments.

FIG. 3 is a circuit diagram of an example of the T/R switch unit according to some embodiments.

FIG. 4 is a flow chart of an example method for transmitting and receiving RF signals in a GaAs based switch according to some embodiments.

### DETAILED DESCRIPTION

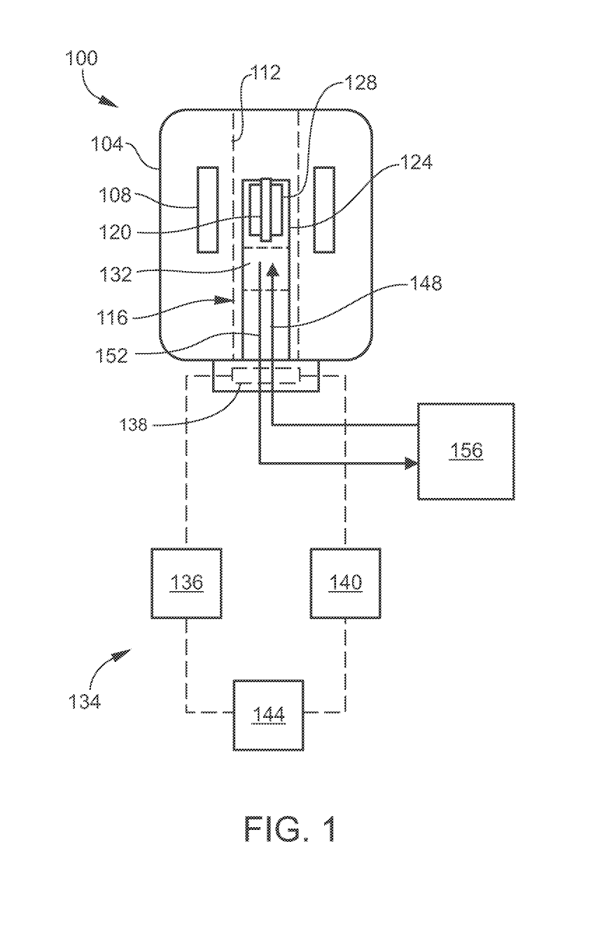

FIG. 1 is a schematic view of an example of a nuclear magnetic resonance (NMR) apparatus and associated system. In the embodiment specifically illustrated, the NMR apparatus is an NMR spectrometer (or spectrometry system) 100 according to some embodiments. Generally, the structure and operation of NMR spectrometers are understood by persons skilled in the art, and thus certain components and features the NMR spectrometer 100 are described briefly to facilitate an understanding of the subject matter taught herein.

The NMR spectrometer 100 may generally include an outer vacuum case (OVC) or housing 104. The OVC 104 may enclose various components, including a magnet 108 for applying a static (and preferably highly homogeneous) magnetic B₀ field in the range of field densities specified for operation. In some embodiments, the magnet 108 is a superconducting magnet (or high temperature superconducting (HTS) magnet) that exhibits superconductivity at low or very low (cryogenic) temperatures. In such embodiments, the NMR spectrometer 100 includes a cryostat, which includes the OVC 104 and an internal cryogenic cooling system. In such embodiments, the OVC 104 is configured for enclosing the magnet 108 and the internal cryogenic cooling system in a gas-tight manner and maintaining the interior of the OVC 104 at a vacuum level to minimize heat transfer. The OVC 104 includes or is coupled to a bore (tube) 112 in which an NMR probe 116 is removably inserted. One axial end of the bore 112 may extend to the exterior of the OVC 104 to facilitate loading and removal of the NMR probe 116 (such as from the bottom). The magnet 108 surrounds the bore 112 and thus the NMR probe 116, and thus is typically annular or toroidal such as in the form of an electromagnet or coil. The magnet 108 is typically oriented and configured for producing axial magnetic field lines along the central axis of the bore 112. The bore 112 may be thermally isolated from the cryogenic interior of the OVC 104, whereby the sample under investigation residing in the bore 112 may be maintained at a temperature controlled independently from the interior of the OVC.

The NMR probe 116 is configured for supporting an NMR tube (sample holder) 120 such that the sample under investigation contained in the NMR tube 120 is positioned properly in the homogeneous magnetic B₀ field. The NMR probe 116 may generally include a probe housing or body 124 containing a radio frequency (RF) coil 128 and NMR probe circuitry (electronics). In some embodiments, the RF coil 128 may schematically represent one or more individual RF coils. That is, separate RF coils may be utilized for transmitting RF excitation signals (thereby applying the above-noted B₁ field) to the sample and for receiving RF signals (NMR measurement signals) from the sample. Alternatively, the RF coil 128 may represent a single RF transmit/receive coil configured for implementing both transmitting and receiving functions. Alternatively, an RF transmit/receive coil may be provided in combination with one or more other RF transmit coils, with the different RF coils being tuned to different resonance frequencies as appreciated by persons skilled in the art. The RF coil(s) may have any suitable configuration, non-limiting examples of which include birdcage coils, saddle coils, Hemholtz coils, loop-gap resonators, slotted tube (e.g., Alderman-Grant style) resonators, scroll coils, etc. The NMR probe circuitry may include various electronics that provide an RF signal interface between the RF coil 128 and an external control/data acquisition system 134 of the NMR spectrometer 100, such as for resonant frequency tuning, impedance matching, filtering, NMR measurement signal amplification (i.e., a low noise preamplifier), etc., as appreciated by persons skilled in the art. For example, the NMR probe circuitry may include tune and match circuitry (located, for example, in a region 132 proximate to the RF coil 128), and a transmit/receive switch (T/R), a filter and, a receiver-side (pre-) amplifier (located, for example, in a region 138 at or near the base of the NMR probe 116).

Generally, the control/data acquisition system (or control/acquisition system) 134 is configured for controlling the RF transmit/receive operations, conditioning and processing the NMR measurement signals acquired from the sample, and producing frequency-domain NMR spectra therefrom. The control/acquisition system 134 may generally include RF transmitting circuitry (electronics) 136 and RF receiving circuitry (electronics) 140 communicating with the NMR probe circuitry, and a controller 144 (e.g., a computing device and associated hardware and software) communicating with the RF transmitting circuitry 136 and RF receiving circuitry 140. The RF transmitting circuitry 136 and RF receiving circuitry 140 selectively communicate with the RF coil 128 and other NMR probe circuitry via the T/R switch. The RF transmitting circuitry 136 is configured for generating RF energy and transmitting RF excitation signals to the RF coil 128 via the T/R switch and other NMR probe circuitry. For this purpose, the RF transmitting circuitry 136 may include a stable RF energy source (e.g., frequency synthesizer), a modulator for configuring the RF source signal according to desired parameters (e.g., amplitude, phase, shape, pulse width, etc.), a signal amplifier for scaling up the gated waveform (e.g., on the order of hundreds of watts), etc. The power level of the RF source signal may be frequency dependent. The phase shifting and pulse gating functions of the modulator may be controlled by a pulse programmer associated with the controller 144. The RF receiving circuitry 140 is configured for receiving, via the NMR probe circuitry and T/R switch, the NMR measurement signals detected by the RF coil 128 and processing the signals as needed to generate NMR spectra. For this purpose, the RF receiving circuitry 140 may include an RF receiver, an analog-to-digital converter (ADC), a phase shifter, a Fourier transform analyzer for converting the time-domain signal to a frequency-domain signal, etc. The RF receiving circuitry 140 may also include a low noise power supply for providing a DC bias to the LNA circuitry. The pre-amplifier provided by the NMR probe circuitry may be considered as the first stage of the RF receiving circuitry 140.

Generally, the controller 144 is configured for controlling the timing and operation of various components of the NMR spectrometer 100, such as the magnet 108, T/R switch, RF transmitting circuitry 136, and RF receiving circuitry 140. The controller 144 may include hardware (microprocessor, memory, etc.) and software components, as appreciated by persons skilled in the art. In FIG. 1 the controller 144 also schematically represents input and output devices that provide a user interface, including a readout or display device for presenting NMR spectra resulting from an experiment, as appreciated by persons skilled in the art.

In operation, before or after the NMR probe 116 is inserted into the bore 112, the sample holder 120 containing the sample to be irradiated is inserted in the NMR probe 116. The sample holder 120 is positioned such that the sample is coaxially surrounded by the RF coil 128 and immersed in the static Bₒ field established by the magnet 108. RF excitation signals are transmitted from the RF transmitting circuitry 136 to the RF coil 128 according to a predefined pulse sequence, and the RF coil 128 applies corresponding periodic magnetic B₁ fields to the sample. In response, the sample emits NMR measurement signals that are processed by the RF receiving circuitry 140 to generate user-interpretable NMR spectra.

In the present embodiment, the NMR probe 116 is configured as a cryogenic probe (cold probe) that maintains the RF coil 128 and NMR probe circuitry at cryogenic temperatures (e.g., 15 to 30 K) during operation. For this purpose, the NMR probe 116 includes a heat exchanger in the probe body 124 and the probe base 138. The probe body 124 may also include a vacuum barrier and/or other means for thermally isolating the NMR tube 120 from the cooled regions of the NMR probe 116, whereby the sample held in the NMR tube 120 may be maintained at room temperature or other, separately controlled temperature. The heat exchanger includes a coolant supply conduit 148 for conducting chilled coolant through the probe body 124 and to the RF coil 128 and NMR probe circuitry, and a coolant return conduit 152 for conducting warm coolant away from the RF coil 128 and NMR probe circuitry. The coolant return conduit 152 may also provide for cooling the T/R switch, the filter and the LNA. The NMR spectrometer 100 includes a cryogenic cooler (cooling system) 156 communicating with the coolant supply conduit 148 and coolant return conduit 152 via respective thermally insulated, vibration-isolated fluid transfer lines, thereby forming a closed-cycle cooling system. Various coolants may be utilized for cryogenic cooling, one typical yet non-limiting example being helium.

The cryogenic cooler 156 may have any configuration suitable for supplying a cryogen to the NMR probe 116. In some embodiments, the cryogenic cooler 156 includes a reservoir providing a source of room temperature helium gas, a compressor for compressing the helium gas, and a cooling unit (coldhead) for chilling the helium gas. In operation, the compressor compresses the helium gas and transfers the compressed helium gas (which may be at or around room temperature) to the cooling unit. A heat exchanger cools the compressor via a suitable heat transfer medium such as water or air. The cooling unit chills the helium gas (e.g., down to about 5 to 20 K). The cool helium gas is then routed through the NMR probe 116 and into thermal contact with the RF coil 128 and NMR probe circuitry. Heat dissipated by the RF coil 128 and NMR probe circuitry is deposited into the helium gas, thereby cooling the RF coil 128 and NMR probe circuitry. The resulting warm helium gas is then routed from the NMR probe 116 back to the cryogenic cooler 156 for re-chilling and then circulated back to the NMR probe 116.

In other embodiments, the cryogenic cooler 156 may utilize a cryogen other than helium. In other embodiments, the cryogenic cooler 156 may supply liquid helium or other liquid cryogen to the NMR probe 116. In some embodiments, the cryogenic cooler 156 may be configured as an open cycle system.

In the context of the present disclosure, two components are in “thermal contact” with each other if one of the components is able to transfer heat to the other component. No intervening thermally insulating barrier (e.g., vacuum barrier or other poorly thermally conductive barrier) exists between the two components to appreciably impair heat exchange between the two components. Typically, the two components in thermal contact with each other are also in spatial proximity to each other. However, no specific limitation is placed on the distance between the two components. The two components in thermal contact with each other may or may not be in physical contact with each other. Thus, depending on the embodiment, the mode of heat transfer may entail convection and/or conduction (as well as radiation).

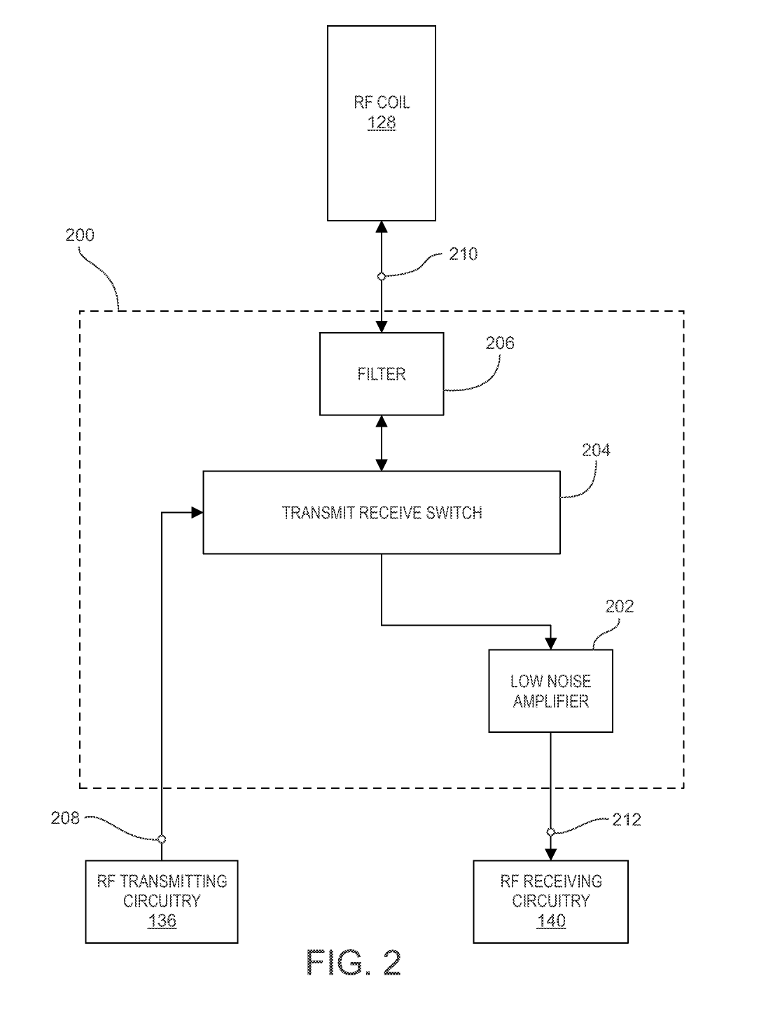

FIG. 2 is block diagram of an example of a cryogenic signal processing device according to some embodiments. In the illustrated embodiment the cryogenic switching device is a transmit/receive switch unit 200, which may be, for example, provided as part of the probe circuitry of an NMR probe as described above (e.g., the NMR probe 116 of FIG. 1). Hence, the transmit/receive switch unit 200 may communicate with RF transmitting circuitry 136 via an RF signal input node 208, an RF coil 128 via a coil interface 210, and RF receiving circuitry 140 via an RF signal output node 212. The RF signal input node 208, coil interface 210, and RF signal output node 212 may be or communicate with RF ports, which may include connectors for cables or other conductors suitable for carrying RF signals. The transmit/receive switch unit 200 may include an amplifier, which in some embodiments may be a low noise (or ultra low noise) amplifier (LNA) 202; a cryogenic switching device, which in the illustrated embodiment is a transmit/receive (T/R) switch 204; and a filter 206.

As appreciated by persons skilled in the art, the T/R switch 204 is operated in coordination with the operations of the RF transmitting circuitry 136 and RF receiving circuitry 140 to isolate and protect the LNA 202 and sensitive components of the RF receiving circuitry 140 from the relatively more intense RF power supplied by the RF transmitting circuitry 136. The signal path between the T/R switch and the RF coil 128 is bidirectional. On the other hand, the respective signal paths between the RF transmitting circuitry 136 and the T/R switch 204, and between the T/R switch 204 and the RF receiving circuitry 140, are unidirectional. The T/R switch routes the strong RF pulses (RF input signals, or RF excitation signals) from the RF transmitting circuitry 136 to the RF coil 128, and routes the relatively weaker RF output signals (NMR measurement signals) from the RF coil 128 to the RF receiving circuitry 140.

With continued reference to FIG. 2, the T/R switch 204 may be configured to receive the RF power at the RF signal input node 208 and transmit the received RF power to the RF coil 128 via a coil interface 210 configured as an output node from the T/R switch unit 200. As an example, the RF power may be transmitted as an RF (NMR) excitation signal to irradiate a sample positioned in the electromagnetic field of the RF coil 128 according to a desired pulse sequence. The filter 206 is positioned to communicate electrically between the T/R switch 204 and the coil interface 210 providing an electrical or RF filtering function on the RF power transmitted to and received from the RF coil 128. As an example, the filter 206 may be a high band pass filter, although any suitable type of filter appropriate for the RF power routed may be used. The T/R switch 204 may be further configured to receive an RF output signal from the NMR probe circuitry 132 via the coil interface 210 configured as an input node. As an example, the RF output signal may be a NMR measurement signal emitted from the sample in response to irradiation by the RF excitation signal. The T/R switch 204 may transmit the received NMR measurement signal to the LNA 202 for pre-amplification and directed transmission or routing to the RF receiving circuitry 140 via the signal output node 212. The LNA 202 may be an extremely power sensitive circuit utilized to boost the relatively weak NMR measurement signals received from the RF coil 128. The LNA 202 may be electrically positioned to transmit the NMR measurement signal via the signal output node 212 to the RF receiving circuitry 140. As noted above, because of the extreme power sensitivity of the LNA 202, it may be necessary to provide sufficient protection from the RF power signal leaked from the RF transmitting circuit 136 via the signal input node 208. This RF power signal is a relatively high power RF signal as compared to the NMR measurement signal received at the coil interface 210 from the RF coil 128.

In some embodiments, the LNA 202 may be configured in a plurality of stages providing phases or steps of pre-amplification. As an example, an LNA 202 may be a one (1) or two (2) stage pre-amplifier. The electrical noise of the LNA 202 itself is injected directly into the received measurement signal while amplifying the received measurement signal. The effect of the electrical noise from subsequent stages of the receive chain of amplifiers is reduced by a factor of the gain of the LNA 202. Thus, it is necessary for an LNA to boost the desired signal power while adding as little noise and distortion as possible, so that the retrieval of the measurement signal is possible in the later stages in the system.

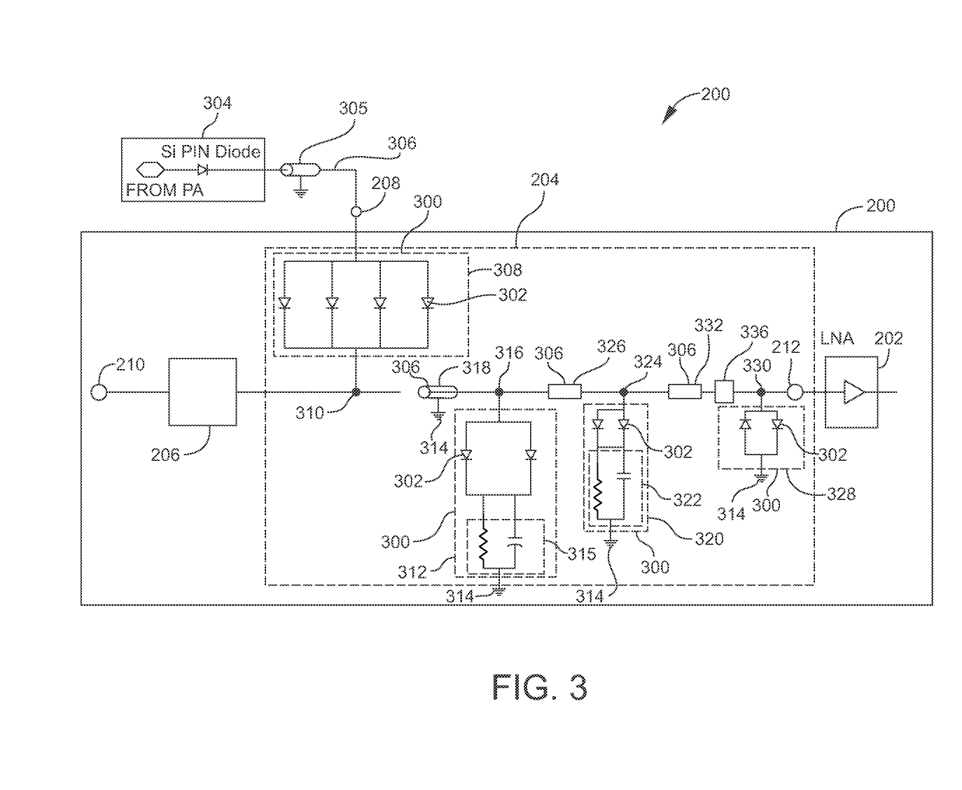

FIG. 3 is a circuit diagram of an example of the T/R switch unit 200 (or cryogenic switching device) according to some embodiments. The T/R switch unit 200 may include a plurality of gallium arsenide (GaAs) diode units 300 for providing the required switching between the RF input signal path and RF output signal path and protection for the LNA 202 device(s). The illustrated embodiment provides four GaAs diode units 300, while other embodiments may provide more or less than four. The GaAs diode units 300 may each include at least one GaAs p-type-intrinsic-n-type (PIN) diode 302. As appreciated by persons skilled in the art, a PIN diode is a diode with a wide, lightly doped intrinsic semiconductor region between a p-type semiconductor and an n-type semiconductor region. The p-type and n-type regions are typically heavily doped because they are used for ohmic contacts. The wide intrinsic region is in contrast to an ordinary p-type-n-type (PN) diode. The wide intrinsic region makes the PIN diode suitable for attenuators, fast switches, photodetectors, and high voltage power electronics applications.

As NMR measurement signals are relatively weak, it is desirable to increase sensitivity by decreasing noise throughout the system. Noise may be a result of either electrical or thermal considerations. Thermal noise may be one of the contributing factors to the noise in any given system. As noted above, thermal noise from a given system with a resistance R at a given temperature is determined by the square root of the product 4kTRB, where better noise reduction may be achieved by decreasing the operating temperatures. One of the components in the system, as described herein, is a switch for transmitting or routing RF input signals and RF output signals. As noted above, the switch conventionally has been based on silicon (Si). However, switches employing Si-based semiconductor PIN diodes have temperature operating range limitations. The temperature range limitations occur because the charges begin to freeze in the material, which occurs around 70 K. Though Si PIN diodes may have long carrier lifetimes (necessary for lower frequencies) and high power handling capabilities, Si PIN diodes limit the operating temperature of the Si-based switch to above 77 K. While thermal noise at an operating temperature of 77 K may be lower relative to the thermal noise at room temperature, because of the extreme sensitivity required of the system, it is desirable to further reduce thermal noise by lowering the operating temperature to below 77 K.

According to the present disclosure, by utilizing GaAs based PIN diodes 302 the operating temperature may be reduced to below 77 K. As an example, it may be desirable to reduce the operating temperature to about 35 K or lower. According to the present disclosure, this may be achieved by utilizing GaAs based PIN diodes 302 in an appropriate circuit configuration instead of Si PIN diodes. However, GaAs PIN diodes 302 may have decreased power handling capabilities. Consequently, the GaAs diode units 300 may be configured with a plurality of GaAs PIN diodes 302 using sufficient bias current. In this manner, many of the components in the system, including the filter 206, the T/R switch 204, and the LNA 202 may operate at cryogenic temperatures close to the NMR coil temperature. Thus, the thermal noise from the filter 206, T/R switch 204 and LNA 202 may drop significantly. In addition, the losses from the transmission line that positions the components in electrical communication from the RF coil 128 (FIG. 2) to the LNA 202 may also drop dramatically. As an example, the total noise temperature of the combined devices of the probe circuitry 132, including the filter 206, the T/R switch 204 and the LNA 202 may be below 10 K at an operating temperature of 35 K or lower. In this example, the sensitivity of the combined devices may result in at least a 20% increase in combined device sensitivity over components operating at 77 K. More generally, the operating temperature may be in any range below that of Si-based devices or 77 K. As a further example, the T/R switching unit 200 may operate at temperatures of 45 K or lower.

In the exemplary embodiment of FIG. 3, the T/R switch unit 200 may comprise the filter 206, GaAs PIN diode based T/R switch 204, and the LNA 202. In some embodiments, the LNA 202 may be a two-stage, GaAs based, pseudomorphic high-electron-mobility transistor (pHEMT) ultra low noise amplifier. In some embodiments, the T/R switch unit 200 may be designed on a double-sided RT/duroid® 6002 printed circuit board (PCB) (Rogers Corporation, Rogers, Conn., USA) with the filter 206 and the T/R switch 204 on one side and the LNA 202 on the other side, as an example. Such construction allows sufficient isolation between the transmitter and receiver circuits while also keeping all components at the same operating temperature. The design may be very compact and the resulting interconnections may be short, so losses are kept to a minimum. The T/R switch unit 200 and the T/R switch 204 may be capable of handling a range of RF signal power, for example from 0.02 W to 50 W. In other embodiments, the T/R switch unit 200 and the T/R switch 204 may be configured to operate with a RF signal power input range below 0.02W. The RF signal power may be a pulsed RF signal. In some embodiments, a single Si PIN diode 304 (receiving RF input signals from the power amplifier of the RF transmitting circuitry 136, FIG. 2) may be coupled to the RF signal input node 208 of the T/R switch unit 200 with a transmission line 306 such as a low thermal conductivity half wavelength coaxial cable 305. The single Si PIN diode 304 may be coupled to the RF signal input node 208 to enhance the isolation between the external circuit (not shown) and T/R switch unit 200. This configuration may be used in order to isolate the external circuit and the T/R switch unit 200 because of the capacitance which may occur due to the multiple

GaAs PIN diodes 302 in parallel, as will be discussed herein. As illustrated, the Si PIN diode 304 and transmission line 306 may be external to the T/R switch unit 200, and may be operated at room temperature or at other temperatures above 77 K.

With continued reference to FIG. 3, as noted above the T/R switch unit 200 includes a plurality of GaAs diode units 300. Each GaAs diode unit 300 may include at least one GaAs PIN diode 302. Additionally, each of the GaAs diode units 300 may be in communication with a transmission line 306. The transmission line 306 may include a plurality of transmission line segments. The transmission line segments may be selected based on impedance and/or attenuation requirements of the T/R switch unit 200. Examples of transmission line segments include, but are not limited to, coaxial cable transmission lines, stripline transmission lines, microstrip transmission lines, and other types. The plurality of GaAs diode units 300 may include a first GaAs diode unit 308 positioned in communication between the RF signal input node 208 and the transmission line 306. In some embodiments the first GaAs diode unit 308 may be coupled to a first transmission line node 310. The first GaAs diode unit 308 may include a plurality of GaAs PIN diodes 302, arranged electrically parallel to each other. In an embodiment, four (4) GaAs PIN diodes 302 may be arranged electrically parallel based on the power of the RF signal. It is noted, however, that based on the power requirements received at the RF signal input 208 of the T/R switch unit 200, the T/R switch unit 200 may include more or less than four (4) GaAs PIN diodes 302 and may be so arranged in a parallel or anti-parallel configuration as required. In some embodiments, all of the diodes provided by the first GaAs diode unit 308 are GaAs diodes such as GaAs PIN diodes.

With continued reference to FIG. 3, the T/R switch unit 200 may further include a second GaAs diode unit 312. The second GaAs diode unit 312 may be positioned in communication between the transmission line 306 and a ground rail node 314. The second GaAs diode unit 312 may include at least one GaAs PIN diode 302. Similar to the first GaAs diode unit 308, if the second GaAs diode unit 312 has a plurality of GaAs PIN diodes 302, the GaAs PIN diodes 302 may be arranged in an electrically parallel fashion. The second GaAs diode unit 312 may also include a first resistor-capacitor circuit 315 for bias current and RF impedance tuning The second GaAs diode unit 312 may be configured to operate in combination with the first GaAs diode unit 308 to provide protection from over powering or saturating the LNA 202. The first GaAs diode unit 308 and the second GaAs diode unit 312, where the second GaAs diode unit 312 is placed in a shunt position relative to the transmission line 306 and the LNA 202, may be provided with a bias current applied at the RF signal input node 208.

The second GaAs diode unit 312 may be coupled to a second transmission line node 316 and the ground rail node 314. A first transmission line segment 318 may be positioned between the first transmission line node 310 and the second transmission line node 316 and may, for example, be a coaxial type transmission line. The coaxial type transmission line may be of varying lengths which may be based on the expected frequency of the RF signal received at the RF signal input node 208. As an example, the length of the coaxial type transmission line may be a based on a one quarter wavelength of the RF signal received. An expected RF signal frequency received may have a frequency in the range of, for example, 500 MHz to 900 MHz. However, by applying the bias current at the RF signal input node 208, the first GaAs diode unit 308 and the second GaAs diode unit 312 are placed in a conductive state, thus creating an RF electrical short from the second transmission line node 316 to the ground rail node 314. As the first GaAs diode unit 308 and the second GaAs diode unit 312 are placed in a conductive state by the bias current, the LNA 202 may be protected from an excess power condition. The amount of bias current is selected such that the GaAs PIN diodes 302 have relatively low resistance at the conduction state of the GaAs PIN diodes 302. In addition, the bias current may be applied in a pulsed manner, where the T/R switch unit 200 is placed in a transmit mode as the bias current is applied at the RF signal input node 208 and conversely placed in a receive mode when the bias current is switched off, thus placing the GaAs diode units 308 and 312 in a non-conductive state.

With continued reference to FIG. 3, the T/R switch unit 200 may further include a third GaAs diode unit 320. The third GaAs diode unit 320 may be positioned in communication between the transmission line 306 and a ground rail node 314. The third GaAs diode unit 320 may include at least one GaAs PIN diode 302. Similar to the second GaAs diode unit 312, if the third GaAs diode unit 320 has a plurality of GaAs PIN diodes 302, the GaAs PIN diodes 302 may be arranged in an electrically parallel fashion. The third GaAs diode unit 320 may also include a second resistor-capacitor circuit 322 for bias current and RF impedance tuning The first resistor-capacitor circuit 315 and the second resistor-capacitor circuit 322 may be separately configured so as to have unique tuning characteristics based on the desired configuration. The third GaAs diode unit 320 may be configured to operate in combination with the first GaAs diode unit 308 and the second GaAs diode unit 312 to provide protection from over powering the LNA 202. Similar to the second GaAs diode unit 312, the third GaAs diode unit 320 may be placed in a shunt position relative to the LNA 202. The third GaAs diode unit 320 may be placed in a conductive state as the bias current is applied at the RF signal input node 208.

The third GaAs diode unit 322 may be coupled to a third transmission line node 324 and the ground rail node 314. A second transmission line segment 326 may be positioned between the second transmission line node 316 and the third transmission line node 324 and may be a microstrip type transmission line, though other suitable types of transmission line may be used, including a lumped element quarter wave transmission line, as an example. The microstrip type transmission line may be of varying lengths which may be based on the expected frequency of the RF signal received at the RF signal input node 208. In addition, the characteristics of the second transmission line segment 326 may vary depending upon the desired signal attenuation of the RF signal between the second transmission line node 316 and the third transmission line node 326. However, by applying the bias current at the RF signal input node 208, the first GaAs diode unit 308, the second GaAs diode unit 312 and the third GaAs diode unit 322 may be placed in a conductive state, creating an RF electrical short from the second transmission line node 316 and the third transmission line node 324 to the ground rail node 314. As described herein, the conductive state is desired during the transmit mode of the T/R switch unit 200. As the first GaAs diode unit 308, the second GaAs diode unit 312 and the third GaAs diode unit 322 are placed in a conductive state, the LNA 202 may be protected from an excess power condition. It is further noted that because of the applied bias current and with the GaAs diode units arranged in a shunt position, the range of RF signal input power may vary from, for example, 0.02 W to 50 W.

With continued reference to FIG. 3, the T/R switch unit 200 may include a fourth GaAs diode unit 328. The fourth GaAs diode unit 328 may also include at least one GaAs PIN diode 302. The fourth GaAs diode unit 328 is positioned between a fourth transmission line node 330 and the ground rail node 314. However, in this example embodiment of the GaAs diode unit 300, the GaAs PIN diodes 302 of the fourth GaAs diode unit 328 may be configured in an anti-parallel or back to back configuration, which may also be referred to as a cross configuration. The anti-parallel configuration may be arranged to provide further protective circuitry positioned in a shunt position relative to the LNA 202. In this manner, the fourth GaAs diode unit 328 may be placed in a conductive state by leakage power through the first transmission line segment 318. As an example, if leakage power at the transmission line node 330 is higher than the GaAs PIN diode turn on power at a zero-bias of 10 dBm and the maximum input power of the LNA is around 17 dBm, the LNA may be protected from an over power condition. Thus, in this example, a clean NMR spectrum with non-noticeable or relatively little amplitude and phase distortion may be provided. A third transmission line segment 332 is positioned between the third transmission line node 324 and the fourth transmission line node 330. The third transmission line segment 332 may be, for example, a microstrip type transmission line. Similar to the first transmission line segment 318 and the second transmission line segment 326, the third transmission line segment 332 may be of any suitable type of transmission line based on the RF signal and measurement signal frequencies.. Additionally, a noise matching circuit 336 may be configured on the transmission line between the third GaAs diode unit 322 and the fourth GaAs diode unit 328. The noise matching circuit may also be configured in alternate positions to provide for the most appropriate noise figure for the LNA 202.

In other embodiments, more or fewer GaAs diode units 300 may be used to provide for additional or less protection of the LNA 202. As shown in FIG. 3 the use of four (4) GaAs diode units 300 is a non-limiting example. More generally, one or more of the GaAs diode units 300 may be shunt diode units, i.e., diode units placed in a shunt position relative to the transmission line 306 and the LNA 202 and provided with a bias current applied at the RF signal input node 208. Such shunt diode units may be configured in the same or similar manner as the second GaAs diode unit 312, the third GaAs diode unit 322, and/or the fourth GaAs diode unit 328 described above, or in different combinations of the foregoing. Such shunt diode units may include one or more GaAs PIN diodes, arranged in parallel or anti-parallel with each other, and may or may not also include a resistor-capacitor circuit or similar circuit. If the GaAs PIN diodes in the associated GaAs diode units are arranged in an anti-parallel configuration no bias may be used.

In some embodiments, all diodes utilized in the T/R switch 204 are GaAs diodes such as GaAs PIN diodes.

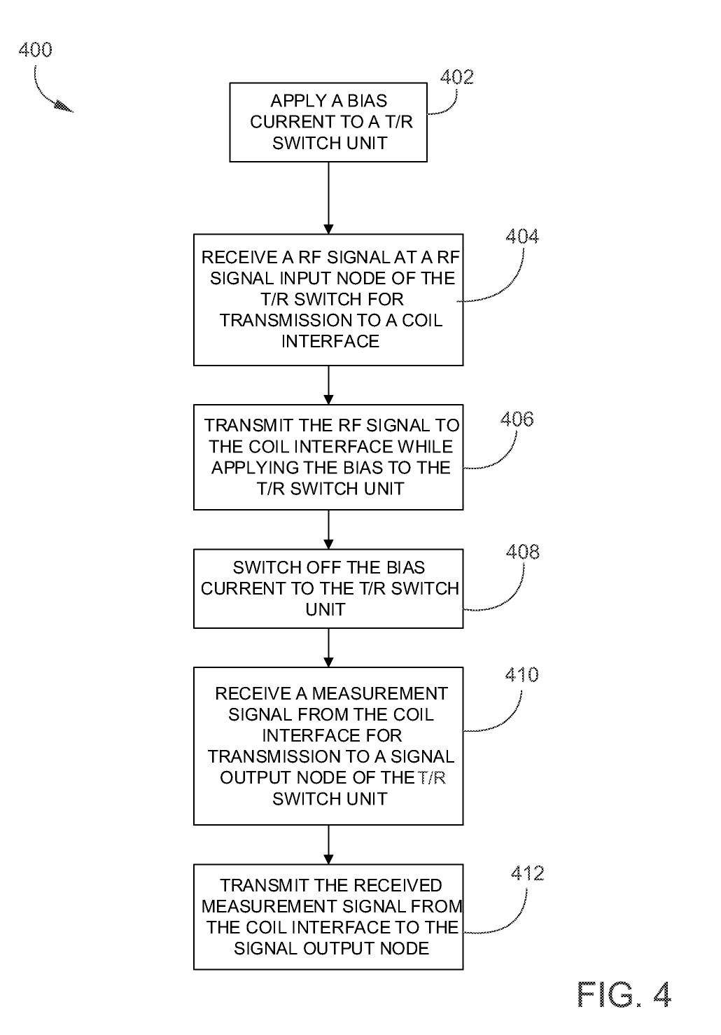

FIG. 4 is a flow chart of an example of a method 400 for transmitting and receiving RF signals in the GaAs based T/R switch unit 200 according to some embodiments. The method 400 may apply 402 the bias current to a T/R switch unit 200 which places a plurality of GaAs diode units 300 in a conductive state. By placing the GaAs diode units 300 in a conductive state the T/R switch unit 200 may be configured to protect the LNA 202 from an over power or over voltage condition as described herein. The method 400 may receive 404 an RF input signal (e.g., an RF excitation signal) at the RF signal input node 208 of the T/R switch unit 200 for transmission to the coil interface 210. The method 400 may transmit 406 the RF input signal to the coil interface 210 while applying the bias to the T/R switch unit 200. The method 400 may switch off 408 the bias current to the T/R switch unit 200. This places the GaAs diode units 300 in a non-conductive state. With the GaAs diode units 300 in a non-conductive state, the method 400 may receive 410 an RF output signal (e.g., an NMR measurement signal) from the coil interface 210 for transmission to the signal output node 212 of the T/R switch unit 200. The method 400 may transmit 412 the received RF output signal from the coil interface 210 to the signal output node 212. The RF output signal may be amplified in one or more stages by the LNA 202 as described herein.

According to some embodiments, FIG. 4 may also be representative of a device configured for performing all or part of the functions or method steps just described.

The present subject matter has been described primarily in the context of an NMR spectrometer. It will be understood, however, that this context is given by way of example only as the present subject matter is applicable to other contexts or operating environments. For example, the NMR apparatus to which the present subject matter is applied may be configured as a (nuclear) magnetic resonance imaging (MRI) apparatus. Accordingly, the term “NMR apparatus” encompasses an NMR spectrometer and an MRI apparatus. More generally, the present subject matter may be applied to a variety of other power dissipating devices that may benefit from cryogenic cooling.

It will be understood that terms such as “communicate” and “in . . . communication with” (for example, a first component “communicates with” or “is in communication with” a second component) are used herein to indicate a structural, functional, mechanical, electrical, signal, optical, magnetic, electromagnetic, ionic or fluidic relationship between two or more components or elements. As such, the fact that one component is said to communicate with a second component is not intended to exclude the possibility that additional components may be present between, and/or operatively associated or engaged with, the first and second components.

It will be understood that various aspects or details of the invention may be changed without departing from the scope of the invention. Furthermore, the foregoing description is for the purpose of illustration only, and not for the purpose of limitation—the invention being defined by the claims.

What is claimed is:

1. A cryogenic switching device, comprising:
a radio frequency (RF) signal input node;
a coil interface;
a transmission line;
an RF signal output node; and
a plurality of gallium arsenide (GaAs) diode units in communication with the RF signal input node, the coil interface and the RF signal output node, and configured for transmitting an RF input signal from the RF signal input node to the coil interface, and for transmitting an RF output signal from the coil interface to the RF signal output node along the transmission line, wherein:
each GaAs diode unit comprises at least one GaAs p-type-intrinsic-n-type (PIN) diode; and
the plurality of GaAs diode units comprises a first GaAs diode unit positioned in communication between the RF signal input node and the transmission line, the first GaAs diode unit comprising a plurality of GaAs PIN diodes arranged electrically parallel to each other.

2. The cryogenic switching device of claim 1, wherein the plurality of GaAs diode units comprises a second GaAs diode unit positioned in communication between the transmission line and a ground rail node, the second GaAs diode unit comprising at least one of:
a plurality of GaAs PIN diodes arranged electrically parallel to each other;
a resistor-capacitor circuit; and
both of the foregoing.

3. The cryogenic switching device of claim 2, wherein the plurality of GaAs diode units comprises a third GaAs diode unit positioned in communication between the transmission line and the ground rail node, and arranged electrically parallel to the second GaAs diode unit, the third GaAs diode unit comprising at least one of:
a GaAs PIN diode arranged electrically parallel to other present GaAs PIN diodes;
a resistor-capacitor circuit; and
both of the foregoing.

4. The cryogenic switching device of claim 3, wherein the plurality of GaAs diode units comprises a fourth GaAs diode unit positioned in communication between the transmission line and the ground rail node, and wherein the fourth GaAs diode unit comprises at least two GaAs PIN diodes, and the at least two GaAs PIN diodes are configured in an anti-parallel manner.

5. The cryogenic switching device of claim 1, wherein the transmission line comprises a plurality of transmission line segments, each transmission line segment positioned in communication between two of the GaAs diode units.

6. The cryogenic switching device of claim 1, comprising a ground rail node, wherein:
the transmission line comprises a first transmission line node, a second transmission line node, a third transmission line node, and a fourth transmission line node;
the first GaAs diode unit is positioned in communication between the RF signal input node and first transmission line node; and
the plurality of GaAs diode units further comprises:
a second GaAs diode unit positioned in communication between the second transmission line node and the ground rail node;
a third GaAs diode unit positioned in communication between the third transmission line node and the ground rail node; and
a fourth GaAs diode unit positioned in communication between the fourth transmission line node and the ground rail node.

7. The cryogenic switching device of claim 6, further comprising:
a first transmission line segment positioned in communication between the first transmission line node and the second transmission line node; and
wherein the first transmission line segment is of a coaxial transmission line type of a pre-determined length.

8. The cryogenic switching device of claim 7, further comprising:
a second transmission line segment positioned in communication between the second transmission line node and the third transmission line node; and
wherein the second transmission line segment is a microstrip transmission line type.

9. The cryogenic switching device of claim 8, further comprising:
a third transmission line segment positioned in communication between the third transmission line node and the fourth transmission line node; and
wherein the third transmission line segment is a microstrip transmission line type.

10. The cryogenic switching device of claim 1, wherein the plurality of GaAs diode units comprises one or more shunt diode units placed in a shunt position relative to the transmission line.

11. The cryogenic switching device of claim 10, wherein the first GaAs diode unit and the one or more shunt diode units are configured to be biased in a conductive state in response to a bias current applied to the RF signal input node.

12. The cryogenic switching device of claim 10, wherein one or more of the shunt diode units comprise at least one of:
a plurality of GaAs PIN diodes arranged electrically parallel to each other;
a plurality of GaAs PIN diodes arranged electrically parallel to each other, and a resistor-capacitor circuit; and
a plurality of GaAs PIN diodes arranged electrically anti-parallel to each other.

13. A cryogenic signal processing device, comprising:
the cryogenic switching device of claim 1; and
an amplifier in communication with the cryogenic switching device.

14. The cryogenic signal processing device of claim 13, wherein the amplifier is a GaAs amplifier positioned in communication between the plurality of GaAs diode units and the signal output node.

15. The cryogenic signal processing device of claim 13, comprising an RF coil in communication with the coil interface.

16. A method of transmitting an RF signal in a transmit/receive (T/R) switch unit, comprising:
applying a bias current to a T/R switch unit comprising a plurality of gallium arsenide (GaAs) diode units, wherein each GaAs diode unit comprises at least one GaAs p-type-intrinsic-n-type (PIN) diode;
receiving an RF input signal at a RF signal input node of the T/R switch unit for transmission to a coil interface via a first GaAs diode unit positioned in communication between the RF signal input node and a transmission line, the first GaAs diode unit comprising a plurality of GaAs PIN diodes arranged electrically parallel to each other;
transmitting the RF input signal to the coil interface while applying the bias to the T/R switch unit;
switching off the bias current to the T/R switch unit;
receiving an RF output signal from the coil interface for transmission to a signal output node of the T/R switch unit; and
transmitting the received RF output signal from the coil interface to the signal output node.

17. The method of claim 16, wherein applying the bias to the T/R switch further comprises applying the bias to the plurality of gallium arsenide (GaAs) diode units.

18. The method of claim 17, wherein applying the bias to the T/R switch further comprises applying the bias to a second GaAs diode unit positioned in communication between the transmission line and a ground rail node, the second GaAs diode unit comprising at least one of:
a plurality of GaAs PIN diodes arranged electrically parallel to each other;
a resistor-capacitor circuit; and
both of the foregoing.

19. The method of claim 18, wherein applying the bias to the T/R switch further comprises applying the bias to a third GaAs diode unit positioned in communication between the transmission line and the ground rail node, and arranged electrically parallel to the second GaAs diode unit, the third GaAs diode unit comprising at least one of:
a plurality of GaAs PIN diodes arranged electrically parallel to each other;
a resistor-capacitor circuit; and
both of the foregoing.

20. The method of claim 16, comprising cooling the T/R switch unit to an operating temperature in a range selected from the group consisting of: 77 K or lower; 45 K or lower; and 35 K or lower.
